(19) United States
(12) Patent Application Publication
(10) Pub. No.: US 2026/0133222 A1
(43) Pub. Date: May 14, 2026

(54) PROBE NEEDLE, PROBE CARD STRUCTURE AND METHOD OF TESTING A DEVICE UNDER TEST

(71) Applicant: Taiwan Semiconductor Manufacturing Company, Ltd., Hsinchu (TW)

(72) Inventors: Shu An Shang, Kaohsiung City (TW); Kuan Chun Chen, Hsinchu City (TW); Guang-Sing Huang, Hsinchu County (TW); Kai-Yi Tang, New Taipei City (TW); Chuei-Tang WANG, Taichung City (TW)

(73) Assignee: Taiwan Semiconductor Manufacturing Company, Ltd., Hsinchu (TW)

(21) Appl. No.: 18/948,432

(22) Filed: Nov. 14, 2024

(51) Int. Cl. G01R 1/067; G01R 1/073; G01R 31/28

(52) U.S. Cl. CPC G01R 1/0675; G01R 1/06761; G01R 1/07342; G01R 31/2886

(57) ABSTRACT

A probe needle for testing a device under test (DUT) includes a needle core; a needle coat; and an isolation layer disposed between the needle coat and the needle core, wherein in an extending direction of the needle core, the isolation layer extends exceeding the needle coat and the needle core extends exceeding the isolation layer. A probe card structure including the probe needle having a needle core; a needle coat; and an isolation layer and a method of testing a device under test using the probe card structure are also provided.

### BACKGROUND

Probe cards with probe needles are utilized for testing continuity of conductive layers (e.g., conductive vias, conductive lines, conductive traces, etc.) that form electrical connections within a device under test (DUT). For example, the DUT may be a semiconductor wafer that has been processed and manufactured to include one or more conductive layers to form various electrical connections within the semiconductor wafer. The probe needles of a probe card may be brought into contact with these one or more conductive layers and an electrical signal may be introduced and passed through these one or more conductive layers through the needles of the probe card.

### BRIEF DESCRIPTION OF THE DRAWINGS

FIG. 1 schematically illustrates a cross-sectional view of a probe card structure in accordance with some embodiments of the disclosure.

FIG. 2 schematically illustrates a cross-sectional view of a probe card structure in accordance with some embodiments of the disclosure.

FIGS. 3 to 5 schematically illustrate various probe needles in accordance with some embodiments of the disclosure.

FIGS. 6 to 8 schematically illustrate cross-sectional views of probe needles in accordance with some embodiments of the disclosure.

FIGS. 9 to 11 schematically illustrate cross-sectional views of probe needles in accordance with some embodiments of the disclosure.

FIG. 12 schematically illustrates a cross-sectional view of a probe card structure in accordance with some embodiments of the disclosure.

FIG. 13 schematically illustrates a cross-sectional view of a probe card structure in accordance with some embodiments of the disclosure.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

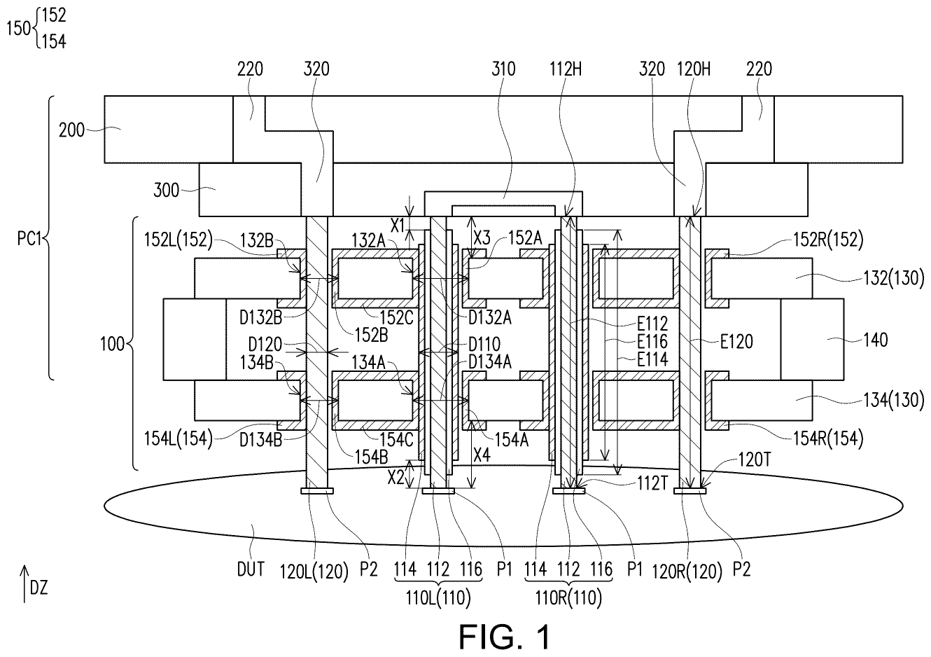

FIG. 1 schematically illustrates a cross-sectional view of a probe card structure in accordance with some embodiments of the disclosure. A probe card structure PC1 in FIG. 1 includes a probe head 100, a supporting plate 200 and a multi-layer organic (MLO) substrate structure 300. The probe head 100 is disposed on the supporting plate 200 and the MLO substrate structure 300 is disposed between the probe head 100 and the supporting plate 200. When testing, the probe card structure PC1 is placed on a device under test DUT with the probe head 100 being between the MLO substrate structure 300 and the device under test DUT.

In some embodiments, the probe head 100 includes at least one first probe needle 110 and at least one second probe needle 120. In FIG. 1, two first probe needles 110 and two second probe needles 120 are shown for descriptive purpose, but the quantities of the first probe needles 110 and the second probe needles 120 are not limited thereto. The MLO substrate structure 300 includes multiple layers of organic materials formed between one or more conductive layers. For example, the MLO substrate structure 300 includes a loop back circuit 310 and a ground circuit 320 form between the organic layers. In addition, the support plate 200 may be a printed circuit board and at least include a ground circuit 220 that is electrically connected to the ground circuit 320 formed in the MLO substrate structure 300. The first probe needle 110 is electrically connected to the loop back circuit 310. Specifically, the loop back circuit 310 may electrically connect two of the first probe needles 110 to form a loop back testing circuit. The second probe needle 120 is electrically connected to the ground circuit 320 formed in the MLO substrate structure 300. Therefore, the second probe needle 120 is electrically grounded. When testing the device under test DUT, the first probe needle 110 extends between the loop back circuit 310 in the MLO substrate structure 300 and an I/O conductor P1 of the device under test DUT, and the second probe needle 120 extends between the ground circuit 320 and the ground conductor P2 of the device under test DUT. Each of the first probe needles 110 and the second probe needles 120 forms a signal transmission path between the MLO substrate structure 300 and the device under test DUT.

The first probe needle 110 includes a needle core 112, a needle coat 114 and an isolation layer 116. The isolation layer 116 is disposed between the needle coat 114 and the needle core 112. In some embodiments, the needle core 112 of the first probe needle 110 include an elongate structure composed of a suitable electrically conductive material, such as a metal or metal alloy. The needle coat 114 is the outermost layer of the first probe needle 110, surrounds the needle core 112 and is made of a conductive material. In some embodiments, the needle coat 114 may be made of a conductive material different from the needle core 112, but the disclosure is not limited thereto. The isolation layer 116 is made of dielectric material and interposed between the needle core 112 and the needle coat 114 so that the needle core 112 is electrically independent from the needle coat 114 by the isolation of the isolation layer 116. The second probe needle 120 has an elongate structure composed of a suitable electrically conductive material, such as a metal or metal alloy. In some embodiments, the second probe needle 120 may have a one-piece structure, but the disclosure is not limited thereto. In some embodiments, the material of the second probe needle 120 may be the same as the needle core 112.

The needle core 112 of the first probe needle 110 may have the extending length E112 substantially the same as the extending length E120 of the second probe needle 120. Specifically, the needle core 112 has a needle head 112H connected to the MLO substrate structure 300 and a needle tip 112T opposite to the needle head 112. Similarly, the second probe needle 120 has a needle head 120H connected to the MLO substrate structure 300 and a needle tip 120T opposite to the needle head 120. When testing the device under test DUT, a needle tip 112T of the needle core 112 is in contact with the I/O conductor P1 of the device under test DUT. In addition, the needle tip 120T of the second probe needle 120 is in contact with the ground conductor P2 of the device under test DUT. Accordingly, the second probe needle 120 and the needle core 112 of the first probe needle 110 establish the electric transmission paths between the MLO substrate structure 300 and the device under test DUT for testing.

In an extending direction (such as the direction DZ shown in FIG. 1) of the needle core 112, the isolation layer 116 extends exceeding the needle coat 114 and the needle core 112 extends exceeding the isolation layer 116. For example, the extending length E112 of the needle core 112 is greater than the extending length E116 of the isolation layer 116 and the extending length E116 of the isolation layer 116 is greater than the extending length E114 of the needle coat 114. In some embodiments, in the extending direction of the needle core 112, the extending length E114 of the needle coat 114 is substantially 55% to 90% of the extending length E112 of the needle core 112. The extending length E116 of the isolation layer 116 is between the extending length E114 of the needle coat 114 and the extending length E112 of the needle core 112.

In some embodiments, in the extending direction, such as the direction DZ, the needle coat 114 is spaced from the needle head 112H of the needle core 112 by at least a first distance X1 and is spaced from the needle tip 112T of the needle core 112 by at least a second distance X2. In some embodiments, the first distance X1 is smaller than the second distance X2, but the disclosure is not limited thereto. In some embodiments, the first distance X1 is ranged from 10 micrometers to 300 micrometers. In some embodiments, the second distance X2 is ranged from 50 micrometers to 600 micrometers. Accordingly, the needle coat 114 is not in contact with the device under test DUT and the MLO substrate structure 300.

The probe head 100 further includes a pair of guide plates 130 and a spacer 140. The first probe needles 110 and the second probe needles 120 are guided by the pair of the guide plates 130 so that the positions of the first probe needles 110 and the second probe needles 120 are fixed. The pair of guide plates 130 includes an upper guide plate 132 and a lower guide plate 134. The upper guide plate 132 is relative closer to the support substrate 200 than the lower guide plate 134. The spacer 140 is disposed between the upper guide plate 132 and the lower guide plate 134 so that the upper guide plate 132 and the lower guide plate 134 are separated from each other by a predetermined gap. In some embodiments, a material of the pair of guide plates 130 includes ceramic materials such as Photoveel, etc. or glass. In some embodiments, a material of the spacer 140 may be a plastic material, a ceramic material, a metallic material, an organic material, silicon, or a combination thereof.

In some embodiments, the upper guide plate 132 is spaced from the needle head 112H of the needle core 112 of the first probe needle 110 by a third distance X3 that may be ranged from 10 micrometers to 300 micrometers. In some embodiment, the distance X3 is greater than the first distance X1. Therefore, the upper guide plate 132 is farther away from the MLO substrate structure 300 than the needle coat 114 of the first probe needle 110. In addition, the lower guide plate 134 is spaced from the needle tip 112T of the needle core 112 of the first probe needle 110 by a fourth distance X4 that may be ranged from 150 micrometers to 700 micrometers. In some embodiments, the distance X4 is greater than the second distance X2. Therefore, the lower guide plate 134 is farther away from the needle tip 112T of the needle core 112 than the needle coat 114. In other words, the needle coat 114 extends exceeding the upper guide plate 132 and the lower guide plate 134 in the direction DZ.

The upper guide plate 132 includes at least one first guide hole 132A and the lower guide plate 134 includes at least one first guide hole 134A. In some embodiments, each first guide hole 132A in the upper guide plate 132 may be corresponding to one corresponding first guide hole 134A in the lower guide plate 134 for accommodating one first probe needle 110. Accordingly, the orientation and the position of each first probe needle 110 is limited by the one first guide hole 132A and the one corresponding first guide hole 134A. In some embodiments, each first guide hole 132A in the upper guide plate 132 may be aligned with one corresponding first guide hole 134A in the lower guide plate 134 in the direction DZ and the first probe needle 110 extends and is oriented along the direction DZ under the guiding effect of the pair of guide plates 130.

In some embodiments, a lateral dimension D132A of each first guide hole 132A may be substantially equal to or slightly greater than a lateral dimension D110 of the corresponding first probe needle 110 inserted therein. Similarly, a lateral dimension D134A of the first guide hole 134A is substantially equal to or slightly greater than a lateral dimension D110 of the corresponding first probe needle 110 inserted therein. As such, the first probe needle 110 is allowed to be inserted into and/or pull out from the first guide hole 132A and the corresponding first guide hole 134A. In some embodiments, the lateral dimension D132A of each first guide hole 132A may be equal to the lateral dimension D134A of the corresponding first guide hole 134A. In some embodiments, the lateral dimension D132A of each first guide hole 132A may be different from the lateral dimension D134A of the corresponding first guide hole 134A.

The upper guide plate 132 further includes at least at least one second guide hole 132B and the lower guide plate 134 further includes at least one second guide hole 134B. Each second guide hole 132B is corresponding to one second guide hole 134B for accommodating one second probe needle 120. Accordingly, the orientation and the position of each second probe needle 120 is limited by one second guide hole 132B and the corresponding second guide hole 134B. For example, one second guide hole 132B is aligned with one correspond second guide hole 134B in the direction DZ and the corresponding second probe needle 120 inserted therein extends and is oriented along the direction DZ under the guiding effect of the pair of guide plates 130.

In addition, a lateral dimension D132B of each second guide hole 132B may be substantially equal to or slightly greater than a lateral dimension D120 of the corresponding second probe needle 120 inserted therein. Similarly, a lateral dimension D134B of the second guide hole 134B is substantially equal to or slightly greater than the lateral dimension D120 of the corresponding second probe needle 120 inserted therein. Accordingly, the position and the orientation of each second probe needle 120 is limited under the guiding effect of the pair of the guide plates 130. In some embodiments, the second probe needle 120 may extend in the direction DZ. In some embodiments, the first probe needle 110 and the second probe needle 120 may be parallel to each other under the guiding effect of the pair of the guide plates 130.

In some embodiments, the probe head 100 further includes at least one adhesive layer 150 disposed on the pair of guide plates 130. In some embodiments, the adhesive layer 150 is a coating layer formed on the surface of at least one of the pair of the guide plates 130 and made of a material that is electric conductive and has good adhesion effect to the guide plates. For example, the material of the adhesive layer 150 includes, but not limited to, Cr, Ti, Al, Ni, W, Pt, Au, or a combination thereof. In some embodiments, the adhesive layer 150 may have a multi-layer structure. In some embodiments, the material of the adhesive layer 150 may be selected based on the material of the corresponding guide plate 130 so that the adhesive layer 150 is firmly coated on the surface of the corresponding guide plate 130. In addition, the adhesive layer 150 may continuously extend between one first probe needle 110 and a corresponding second probe needle 120. In some embodiments, the probe head 100 may include two adhesive layers 150. For example, the adhesive layer 152 is disposed on the upper guide plate 132 and the adhesive layer 154 is disposed on the lower guide plate 134, but the disclosure is not limited thereto.

The adhesive layer 152 on the upper guide plate 132 extends to surround the first guide hole 132A and the second guide hole 132B. For example, a first portion 152A of the adhesive layer 152 extends along the perimeter of the first guide hole 132A and the adhesive layer 152 in the first guide hole 132A is interposed between the needle coat 114 of the first probe needle 110 and the upper guide plate 132. In some embodiments, the first portion 152A of the adhesive layer 152 may surround the entire perimeter of the first guide hole 132A. The needle coat 114 of the first probe needle 110 limited by the first guide hole 132A would be in contact with the first portion 152A of the adhesive layer 152. In some embodiments, the first probe needle 110 may not be closely fit in the first guide hole 132A. Accordingly, a portion of the needle coat 114 of the first probe needle 110 may be in direct contact with the first portion 152A of the adhesive layer 152 and another portion of the needle coat 114 of the first probe needle 110 may be spaced from the first portion 152A of the adhesive layer 152, but the disclosure is not limited thereto.

Similarly, a second portion 152B of the adhesive layer 152 extends along the perimeter of the second guide hole 132B and the second portion 152B of the adhesive layer 152 is interposed between the second probe needle 120 and the upper guide plate 132. The second portion 152B of the adhesive layer 152 may surround the entire perimeter of the second guide hole 132B. In some embodiments, the second probe needle 120 may not be closely fit in the second guide hole 132B. Accordingly, the second probe needle 120 may be partially in contact with the second portion 152B of the adhesive layer 152 while a portion of the second portion 152B of the adhesive layer 152 is spaced from the second probe needle 120.

As shown in FIG. 1, a third portion 152C of the adhesive layer 150 extends between the first portion 152A covering the first guide hole 132A and the second portion 152B covering the second guide hole132B. In addition, the adhesive layer 152 is made of an electric conductive material. Therefore, the adhesive layer 152 establishes a continuous electric transmission path between the needle coat 114 of each first probe needle 110 and a corresponding second probe needle 120. The adhesive layer 152 may include several segments to establish independent electric transmission paths for different first probe needles 110. As shown in FIG. 1, the left segment 152L of the adhesive layer 152 on the upper guide plate 132 forms the electric transmission path between the needle coat 114 of the first probe needle 110L and the second probe needle 120L, and the right segment 152R of the adhesive layer 152 on the upper guide plate 132 forms the electric transmission path between the needle coat 114 of the first probe needle 110R and the second probe needle 120R.

In the embodiment, the left segment 152L is spaced from the right portion 152R. However, in some embodiments, the adhesive layer 152 may be continuously extend on the surface of the upper guide plate 132 so that the needle coat 114 of the first probe needle 110L and the needle coat 114 of the first probe needle 110L may be electrically connected by adhesive layer 152. In some embodiments, the probe head 100 may include one or more other probe needle (not shown) inserted in one or more other guide hole that is not covered and/or surrounded by the adhesive layer 152, such that the one or more other probe needle is not in contact with the adhesive layer 152. Accordingly, some of the probe needles guided by the upper guide plate 132 is not in contact with the adhesive layer 152.

The adhesive layer 154 formed on the surface of the lower guide plate 154 may have a similar design as the adhesive layer 152. Specifically, the adhesive layer 154 may include a left segment 154L and a right segment 154R that is spaced from the left segment 154L. The left segment 154L and the right segment 154R may establish respective electric transmission paths for electrically connecting different first probe needles 110 to the corresponding second probe needles 120. Take the left segment 154L as an example, the adhesive layer 154 may include a first portion 154A covering the first guide hole 134A, a second portion 154B covering the second guide hole 134B, and a third portion 154C continuously extending between the first portion 154A and the second portion 154B, such that the first probe needle 110L is electrically connected to the second probe needle 120L through the left segment 154L of the adhesive layer 154. In addition, the first probe needle 110R may be electrically connected to the second probe needle 120R through the right segment 154R of the adhesive layer 154. Herein, the terms “left” and “right” are used for indicating different segments of the adhesive layer 152/154 in the drawings, but in the real structure, the arrangement of the segments is not limited to be “left and right”.

The method of testing the device under test DUT may include providing the probe card structure PC1 and placing the probe card structure PC1 on the device under test DUT. The device under test DUT may be a semiconductor wafer that has been processed and manufactured to include one or more conductive layers to form various electrical connections within the semiconductor wafer. For example, the device under test DUT includes I/O conductors P1 and ground conductors P2 that are revealed on the surface of the device under test DUT. In some embodiments, the I/O conductors P1 and the ground conductors P2 may be in the form of pads, bumps or the like. The probe card structure PC1 is placed on the device under test DUT so that each first probe needle 110 is in contact with one corresponding I/O conductor P1 and each second probed needle 120 is in contact with one corresponding ground conductor P2. In some embodiments, the first probe needle 110 may be considered as an I/O probe needle and the second probe needle 120 may be considered as a ground probe needle.

During testing the device under test DUT, the needle core 112 of one first probe needle 110 is electrically connected to the needle core 112 of another first probe needle 110 through the loop back circuit 310 formed in the MLO substrate structure 300. Therefore, the two first probe needles 110 enables the signals of the corresponding I/O conductors P1 to be looped back, which is applicable to a digital signal testing. Simultaneously, the second probe needle 120 is electrically grounded through the ground circuit 320 formed in the MLO substrate structure 300 and the ground circuit 220 formed in the support plate 220. In addition, the needle coat 114 of each first probe needle 110 is electrically to a corresponding second probe needle 120 through the adhesive layer 152 formed on the upper guide plate 132 and the adhesive layer 154 formed on the lower guide plate 134. Therefore, the needle coat 114 of each first probe needle 110 is electrically grounded. In each first probe needle 110, the needle coat 114 is electrically isolated from the needle core 112 and thus the needle coat 114 provides the shielding effect during testing. The signal transmission effect of the needle core 112 of each first probe needle 110 is improved by the shielding effect of the electrically grounded needle coat 114.

For example, the signals transmitted in adjacent two of the first probe needles 110 are prevented from the cross-talk interference by the shielding effect of the electrically grounded needle coat 114. In addition, the first probed needle 110 may provide high levels of signal integrity and quality since the transmission impedance of the first probe needle 110 is controlled by the coupling effect between the needle core 112 and the electrically grounded needle coat 114. In some embodiments, the first probe needle 110 enable high speed digital signal testing and the high speed may refer to a data transmission speed greater than 30 Gbps. The first probe needle 110 has integrated shielding structure (the needle coat 114) so that the disposition position of the first probe needle 110 is not limited to the position of the ground needle (the second probe needle 120), which improves the flexibility of the arrangement of the first probe needles 110.

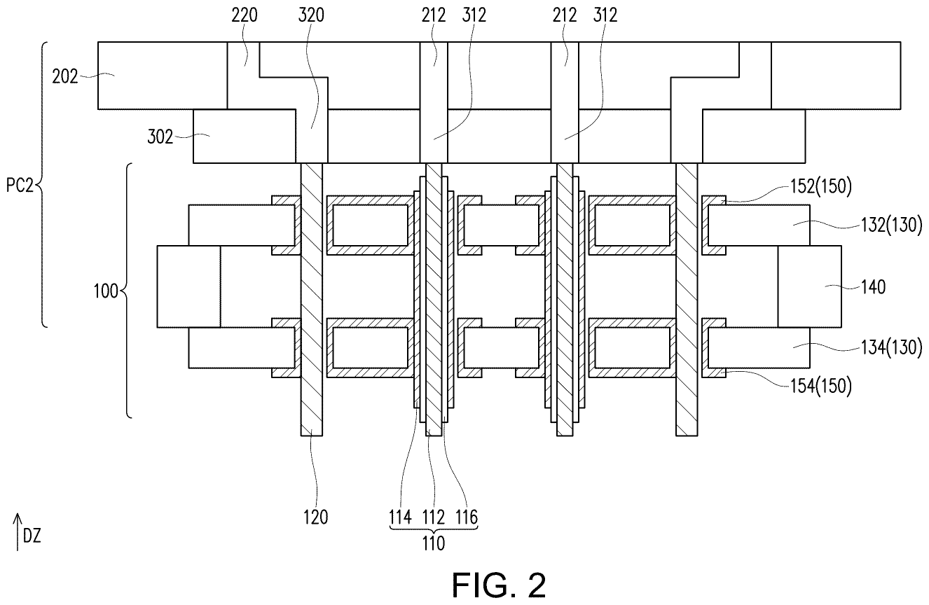

FIG. 2 schematically illustrates a cross-sectional view of a probe card structure in accordance with some embodiments of the disclosure. A probe card structure PC2 shown in FIG. 2 includes a probe head 100, a support plate 202 and an MLO substrate structure 302, in which the probe head 100 is similar to the probe head 100 depicted in FIG. 1. The same reference numbers described in the embodiments of FIG. 1 and FIG. 2 represent the same or equivalent components and thus the descriptions for these components are applicable to both embodiments of FIG. 1 and FIG. 2. Specifically, referring to the descriptions of the embodiment of FIG. 1, the probe head 100 includes at least one first probe needle 110, at least one second probe needle 120, a pair of guide plates 130, a spacer 140 and adhesive layers 150. Each first probe needle 110 includes a needle core 112, a needle coat 114, and an isolation layer 116 isolating the needle coat 114 from the needle core 112. The guide plates 130 include an upper guide plate 132 and a lower guide plate 134 spaced from the upper guide plate 132 by the spacer 140. The adhesive layers 150 include an adhesive layer 152 disposed on the surface of the upper guide plate 132 and an adhesive layer 154 disposed on the surface of the lower guide plate 134. The disposition relationships of the components of the first probe needle 110 may refer to those of the embodiment of FIG. 1 and not be reiterated.

As shown in FIG. 2, the support plate 202 may be a printed circuit board and include one or more conductive layers laminated on/in a board to form required electrical transmission routes. In some embodiments, the support plate 202 at least includes an electrical circuit 212 and a ground circuit 220. The MLO substrate structure 302 includes one or more conductive layers /sposed/ embedded between multiple layers of organic materials. For example, the MLO substrate structure 302 at least includes an electric circuit 312 and a ground circuit 320. The MLO substrate structure 302 is disposed between the probe head 100 and the support plate 202. The electric circuit 212 in the support plate 202 is connected to the electric circuit 312 in the MLO substrate structure 302 and the first needle core 112 of each first probe needle 110 in the probe head 100 is connected to the corresponding electric circuit 312 in the MLO subtract structure 302. Accordingly, the signals of different first probe needles 110 are transmitted by different electric circuits 312 in the MLO subtract structure 302, which forms direct testing channels for different first probe needles 110 and is applicable to a high frequency test. In some embodiments, the high frequency may refer to a frequency greater than 10 GHz. In some embodiments, the probe card structure PC2 may be used for RFIC test that requires a high frequency direct channel test. In addition, the signal reflection of the first probe needle 110 is reduced since the transmission impedance of the first probe needle 110 would be controlled by the electrically grounded needle coat 114. The first probed needle 110 may provide high levels of signal integrity and quality.

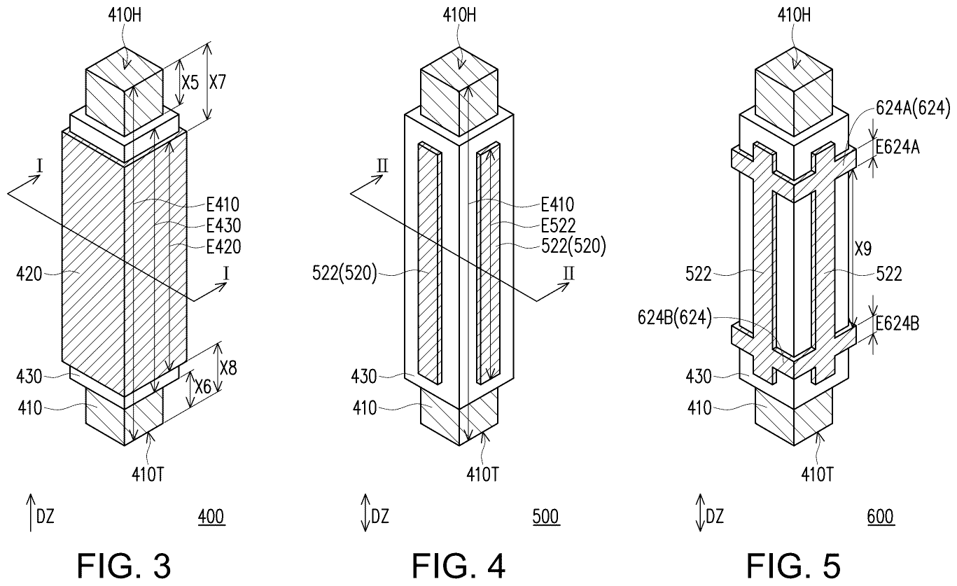

FIGS. 3 to 5 schematically illustrate various probe needles in accordance with some embodiments of the disclosure. The probe needles shown in FIGS. 3 to 5 may serve as implemental examples of the first probe needle 110 depicted in any of the previous embodiments. In FIG. 3, a probe needle 400 includes a needle core 410, a needle coat 420 and an isolation layer 430. The isolation layer 430 is disposed between the needle core 410 and the needle coat 420 so that the needle core 410 is not in contact with the needle coat 420. The materials of the needle core 410 and the needle coat 420 are electrically conductive and the material of the isolation layer 420 is electrically insulated so that the needle core 410 and the needle coat 420 are electrically independent from each other. In the direction DZ that is an extending direction of the needle core 410, the isolation layer 430 extends exceeding the needle coat 420 and the needle core 410 extends exceeding the isolation layer 420. Accordingly, the needle core 410 is partially exposed by the isolation layer 430 and the isolation layer 430 is partially exposed by the needle coat 420. In some embodiments, the isolation layer 430 covers a first area of a sidewall of the needle core 410, and the needle coat 420 covers a second area of a sidewall of the isolation layer 430, wherein the first area is larger than the second area.

The needle core 410 is an elongated and solid structure extending in the direction DZ. The needle core 410 has a needle head 410H configured to be connected to the MLO substrate structure 300/302 depicted in FIG. 1/2 and a needle tip 410T opposite to the needle head 410H and configured to contact the device to be test. The needle core 410 shown in FIG. 3 has a shape of square prism, but the disclosure is not limited thereto. In some embodiments, the needle tip 410T may have a tapper shape according to various designs, but the disclosure is not limited thereto. In some embodiments, the needle core 410 has an elongated shape with a cross-section of a circle, a polygon, or other shapes.

The isolation layer 430 is disposed on the side surfaces of the needle core 410 and laterally surround the entire perimeter of the needle core 410. An extending length E430 of the isolation layer 430 is smaller than an extending length E410 of the needle core 410. The isolation layer 430 is spaced from the needle head 410H by a distance X5 and spaced from the needle tip 410T by a distance X6. Therefore, the isolation layer 430 substantially covers the middle section of the needle core 412. In some embodiments, the distance X5 may be smaller than the distance X6. In some embodiments, the distance X6 may be ranged from 50 micrometers to 500 micrometers.

The needle coat 420 is disposed on the side surfaces of the isolation layer 430 and laterally surround the entire perimeter of the isolation layer 430. An extending length E420 of the needle coat 420 is smaller than the extending length E430 of the isolation layer 430. In some embodiments, in the direction DZ, i.e. the extending direction of the needle core 410, the extending length E420 of the needle coat 420 is substantially 55% to 90% of the extending length E410 of the needle core 410. The needle coat 420 is spaced from the needle head 410H by a distance X7 and spaced from the needle tip 410T by a distance X8. In some embodiments, the distance X7 is ranged from 10 micrometers to 300 micrometers. In some embodiments, the distance X8 is ranged from 50 micrometers to 600 micrometers. In some embodiments, the distance X8 may be greater than the distance X7. In the distance DZ, the isolation layer 430 extends exceeding the needle coat 420. For example, a portion of the isolation layer 430 is exposed by the needle coat 420 and extends between the needle coat 420 and the needle head 410H of the needle core 410 in the direction DZ, and another portion of the isolation layer 430 is exposed by the needle coat 420 and extends between the needle coat 420 and the needle tip 410T of the needle core 410 in the direction DZ.

In FIG. 4, a probe needle 500 is an implemental example of the first probe needle 110 in the embodiments of FIG. 1 and FIG. 2 and includes a needle core 410, a needle coat 520 and an isolation layer 430, in which the needle core 410 and the isolation layer 430 are similar and/or equivalent to the those depicted in FIG. 3 and thus the descriptions for the needle core 410 and the isolation layer 430 in FIG. 3 is applicable to the embodiment of FIG. 4. In the embodiment, the needle coat 520 has a different structure from the needle coat 420 in FIG. 3. The needle coat 520 includes elongation portions 522 extending in the direction DZ, i.e. the extending direction of the needle core 410 and arranged along the perimeter of the isolation layer 430. Specifically, the elongation portions 522 are laterally spaced from one another.

In the embodiment, the needle core 410 is a square prism and has four side surfaces each elongated along the direction DZ, and the needle coat 520 includes four elongation portions 522 respectively disposed on the side surfaces of the needle core 410 with the isolation layer 430 interposed between the needle core 410 and the needle coat 520. The extending lengths E522 of the elongation portions 522 may be designed in a manner similar to the needle coat 420 in FIG. 3. For example, the extending length E522 of each elongation portion 522 may be substantially 55% to 90% of the extending length E410 of the needle core 410. The extending lengths E522 of the elongation portions 522 are designed so that a portion of the isolation layer 430 extends between the elongation portions 522 and the needle head 410H of the needle core 410 in the direction DZ, and another portion of the isolation layer 430 extends between the elongation portions 522 and the needle tip 410T of the needle core 410 in the direction DZ. In addition, the isolation layer 430 extends laterally between the elongation portions 522. In some embodiments, the transmission impedance of the probe needle 500 may be determined by at least the area of the needle coat 520 due to the coupling effect between the needle core 410 and the needle coat 520. Accordingly, the area of each elongation portions 522 may be modified based on the design requirement.

In FIG. 5, a probe needle 600 may be an implemental example of the first probe needle 110 in the embodiments of FIG. 1 and FIG. 2 and includes a needle core 410, a needle coat 620 and an isolation layer 430, in which the needle core 410 and the isolation layer 430 are similar and/or equivalent to the those depicted in FIG. 3 and thus the descriptions for the needle core 410 and the isolation layer 430 in FIG. 3 is applicable to the embodiment of FIG. 5. The needle coat 620 includes elongation portions 522 and lateral portions 624. The elongation portions 522 are similar to those depicted in FIG. 4 and the descriptions for the elongation portion 522 in FIG. 4 is applicable to the embodiments of FIG. 5. In FIG. 5, each of the lateral portions 624 extends continuously between adjacent two of the elongation portions 522. As shown in FIG. 5, the elongation portions 522 and the lateral portions 624 forms a fence shape structure encircling the needle core 410.

The lateral portions 624 include upper lateral portions 624A and lower lateral portions 424B. The upper lateral portions 624A are disposed at a level more adjacent to the needle head 410H of the needle core 410 than the lower lateral portions 624B. The upper lateral portions 624A are spaced from the lower lateral portions 624B by a distance X9. In the case the probe needle 600 is applied to the embodiment of FIG. 1 or FIG. 2, the distance X9 is corresponding to the spacing distance between the upper guide plate 132 and the lower guide plate 134 so that the upper lateral portions 624A and the lower lateral portions 624B are allowed to be in contact with the adhesive layers 150.

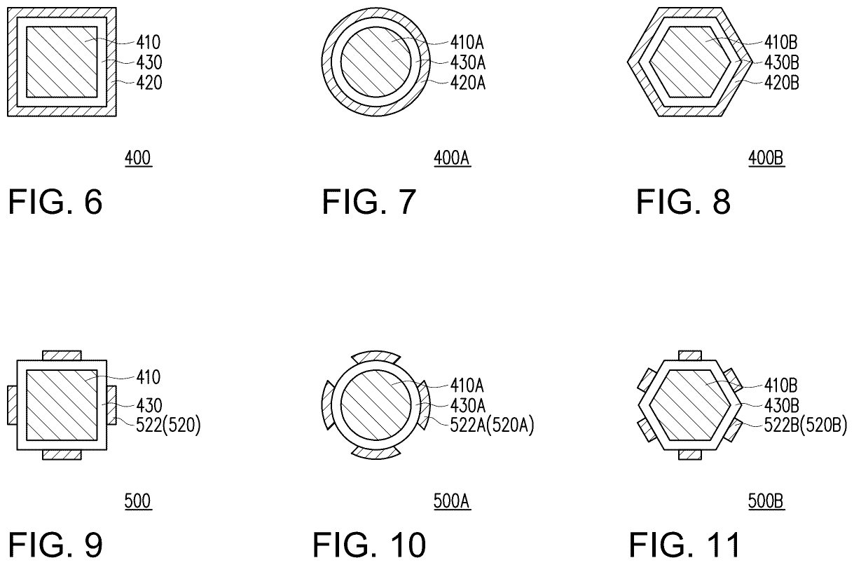

FIGS. 6 to 8 schematically illustrate cross-sectional views of probe needles in accordance with some embodiments of the disclosure. The cross-sectional view shown in FIG. 6 is taken from line I-I in FIG. 3. Referring to FIG. 3 and FIG. 6, the probe needle 400 include the needle core 410, the needle coat 420 and the isolation layer 430 interposed between the needle core 410 and the needle coat 420. FIG. 6 shows that the cross-section of the needle core 410 taken along line I-I has a square shape and FIG. 6 presents the probe needle 400 in the top view direction. The isolation layer 430 completely encircles the needle core 410 and the needle coat 420 completely encircles the isolation layer 430. The cross-section of the probe needle 410 taken along line I-I has a concentric structure. That is, the probe needle 400 has a co-axial structure. For example, in the top view, the isolation layer 430 forms a ring pattern surrounding the needle core 410 and the needle coat 420 also forms a ring pattern surrounding the isolation layer 430.

FIG. 7 shows a cross-section of a probe needle 400A that is a modified example of the cross-section of the probe needle 400 shown in FIG. 6. The cross-section of the needle core 410A of the probe needle 400A has a circular shape. The isolation layer 430A completely encircles the needle core 410A and the needle coat 420A completely encircles the isolation layer 430A. Therefore, the cross-section of the probe needle 400A has a concentric structure. FIG. 8 shows a cross-section of a probe needle 400B that is another modified example of the cross-section of the probe needle 400 shown in FIG. 6. The cross-section of the needle core 410B of the probe needle 400B has a polygonal shape such as hexagonal shape. The isolation layer 430B completely encircles the needle core 410B and the needle coat 420B completely encircles the isolation layer 430B. Therefore, the cross-section of the probe needle 400B has a concentric structure. In some embodiments, the cross-section of the needle core 410 of the probe needle 400 may be modified to have other polygonal shape such as triangular shape, rectangular shape, pentagonal shape, heptagonal shape, octagonal shape, etc.

FIGS. 9 to 11 schematically illustrate cross-sectional views of probe needles in accordance with some embodiments of the disclosure. The cross-sectional view shown in FIG. 9 is taken from line II-II in FIG. 4. Referring to FIG. 4 and FIG. 9, the probe needle 500 include the needle core 410, the needle coat 520 and the isolation layer 430 interposed between the needle core 410 and the needle coat 520. FIG. 9 shows that the cross-section of the needle core 410 taken along line II-II has a square shape. The isolation layer 430 completely encircles the needle core 410 to have a square perimeter and the elongation portions 522 of the needle coat 520 are respectively disposed on four side edges of the isolation layer 430. In some embodiments, in the top view, the isolation layer 430 forms a ring pattern surrounding the needle core 410 and the needle coat 520 forms separate patterns around the isolation layer 430.

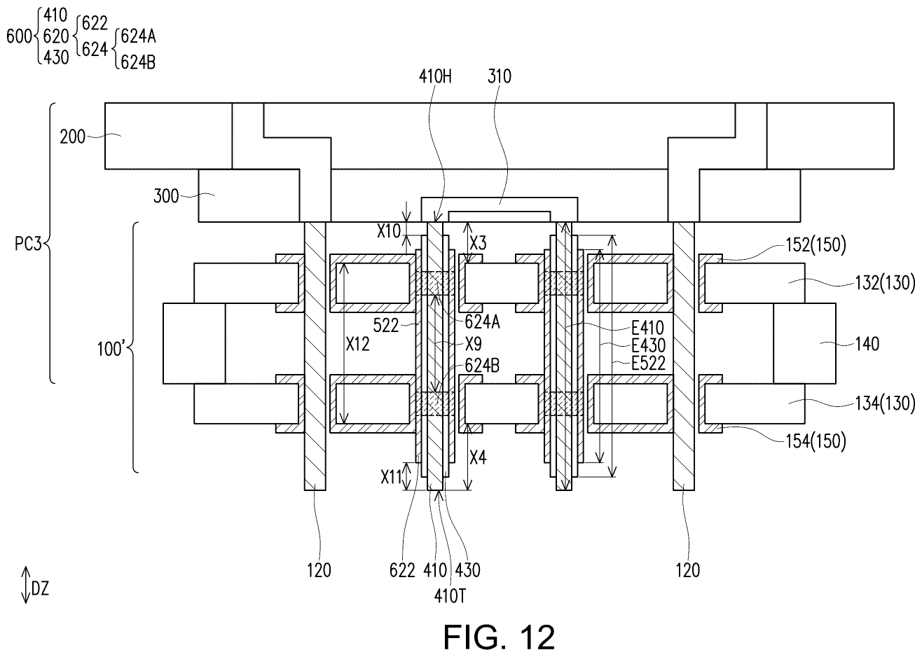

FIG. 10 shows a cross-section of a probe needle 500A that is s modified example of the cross-section of the probe needle 500 shown in FIG. 9. The cross-section of the needle core 410A of the probe needle 500A has a circular shape. The isolation layer 430A completely encircles the needle core 410A. The elongation portions 522A of needle coat 520A are arranged along the circular perimeter of the isolation layer 430A and spaced from each other. Four elongation portions 522A of needle coat 520A are presented herein, but the disclosure is not limited thereto. The quantity of the elongation portions 522A of needle coat 520A may be determined based on various requirements. In some embodiments, in the top view, the isolation layer 430 forms a ring pattern surrounding the needle core 410 and the needle coat 520A forms separate patterns around the isolation layer 430. FIG. 11 shows a cross-section of a probe needle 500B that is another modified example of the cross-section of the probe needle 500 shown in FIG. 9. The cross-section of the needle core 410B of the probe needle 500B has a polygonal shape such as a hexagonal shape. The isolation layer 430B completely encircles the needle core 410B to have a hexagonal perimeter. The elongation portions 522B of the needle coat 520B are respectively disposed on six side edges of the isolation layer 430B. In some embodiments, the cross-section of the needle core 410 of the probe needle 500 may be modified to have other polygonal shape such as triangular shape, rectangular shape, pentagonal shape, heptagonal shape, octagonal shape, etc. In some embodiments, in the top view, the isolation layer 430 forms a ring pattern surrounding the needle core 410 and the needle coat 520B forms separate patterns around the isolation layer 430.

FIG. 12 schematically illustrates a cross-sectional view of a probe card structure in accordance with some embodiments of the disclosure. A probe card structure PC3 shown in FIG. 12 includes a probe head 100′, a support plate 200 and an MLO substrate structure 300, in which the probe card structure PC3 is similar to the probe card structure PC1 depicted in FIG. 1. The same reference numbers described in the embodiments of FIG. 1 and FIG. 12 represent the same or equivalent components and thus the descriptions for these components are applicable to both embodiments of FIG. 1 and FIG. 12. In FIG. 12, the probe head 100′ is different from the probe head 100 in FIG. 1 in that the probe head 100′ includes at least one probe needle 600 depicted in FIG. 5 and further includes at least one second probe needle 120, a pair of guide plates 130, a spacer 140, and adhesive layers 150 that have been described in FIG. 1. In some embodiments, the probe card structure PC3 is an implemental example showing the probe needle 600 depicted in FIG. 5 replaces the first probe needle 110 of the probe head 100 in FIG. 1. Therefore, other components of the probe head 100′ may refer to the description for those components depicted in FIG. 1.

The probe needle 600 includes a needle core 410, a needle coat 620 and an isolation layer 430 interposed between the needle core 410 and the needle coat 620. The needle coat 620 includes elongation portions 522 and lateral portions 624 depicted in FIG. 5. FIG. 12 shows the cross-section of the probe needle 600 taken along the elongation portions 522. For descriptive purpose, FIG. 12 shows the lateral portions 624 by using broken lines since the lateral portions 624 may not be seen in the cross-section taken along the elongation portions 522. In some embodiments, the extending length E522 of each elongation portion 522 is sufficient that each elongation portion 522 extends exceeding the upper guide plate 132 and the lower guide plate 134 in the direction DZ. In some embodiments, the elongation length E522 of the elongation portion 522 may be similar to the elongation length E114 of the needle coat 114 shown in FIG. 1. For example, the extending length E522 of the needle coat 522 is substantially 55% to 90% of the extending length E410 of the needle core 410. In addition, the extending length E430 of the isolation layer 430 is between the extending length E410 of the needle core 410 and the extending length E522 of the needle coat 522.

In some embodiments, each elongation portion 522 is spaced from the needle head 410H of the needle core 410 by a distance X10 and spaced from the needle tip 410T of the needle core 410 by a distance X11, wherein the distance X10 may be smaller than the distance X11, but the disclosure is not limited thereto. In addition, referring to the embodiment of FIG. 1, the upper guide plate 132 may be spaced from the needle head 410H of the needle core 410 by a third distance X3 and the lower guide plate 134 may be spaced from the needle head 410H of the needle core 410 by a fourth distance X4. In some embodiments, the third distance X3 is greater than the distance X10 and the fourth distance X4 is greater than the distance X11. Therefore, the elongation portions 522 are allowed to be laterally in contact with the adhesive layer 152 on the upper guide plate 132 and laterally in contact with the adhesive layer 154 on the lower guide plate 134.

Referring to the embodiment of FIG. 5, the lateral portions 624 includes upper lateral portions 624A and lower lateral portions 624B. FIG. 12 shows that the upper lateral portions 624A are positioned at a level corresponding to the upper guide plate 132 and the lower lateral portions 624B are positioned at a level corresponding to the lower guide plate 134. Therefore, the upper lateral portions 624A are allowed to be in contact with the adhesive layer 152 on the upper guide plate 132, and the lower lateral portions 624B are allowed to be in contact with the adhesive layer 154 on the lower guide plate 134. Specifically, as shown in FIG. 12, each upper lateral portion 624A is spaced from the corresponding lower lateral portion 624B by the distance X9, and the upper surface of the upper guide plate 132 is spaced from the lower surface of the lower guide plate 134 by a distance X12 that is not smaller than the distance X9.

In some embodiments, the lateral portions 624 may connect all the elongation portions 522 to form a continuous structure. Especially, the elongation portions 522 and the lateral portions 624 together encircle the entire perimeter of the isolation layer 430 at the levels of the upper guide plate 132 and the lower guide plate 134. Accordingly, in the case that only a portion of the needle coat 620 is in contact with the adhesive layers 150 formed on the upper guide plate 132 and the lower guide plate 134, the entire needle coat 620 is electrically connected to the adhesive layers 150. Therefore, during testing, the entire needle coat 620 is electrically grounded and provides the shielding effect as the needle coat 114 described in FIG. 1. In some embodiments, the probe needle 600 may optionally include further lateral portions positioned between the upper lateral portions 624A and the lower lateral portions 624B so that the needle coat 620 may have the desired area for achieving the required transmission impedance of the probe needle 600.

The MLO substrate structure 300 includes a loop back circuit 310 and the loop back circuit 310 may electrically connect two of the probe needles 600 to form a loop back testing circuit. When testing a device, the needle coats 620 of the probe needles 600 are electrically grounded through the adhesive layers 150 and the second probe needles 120 to provide the shielding effect. Therefore, the signals transmitted in the probe needles 600 are prevented from cross-talk and the probe needles 600 provide high levels of signal integrity and quality.

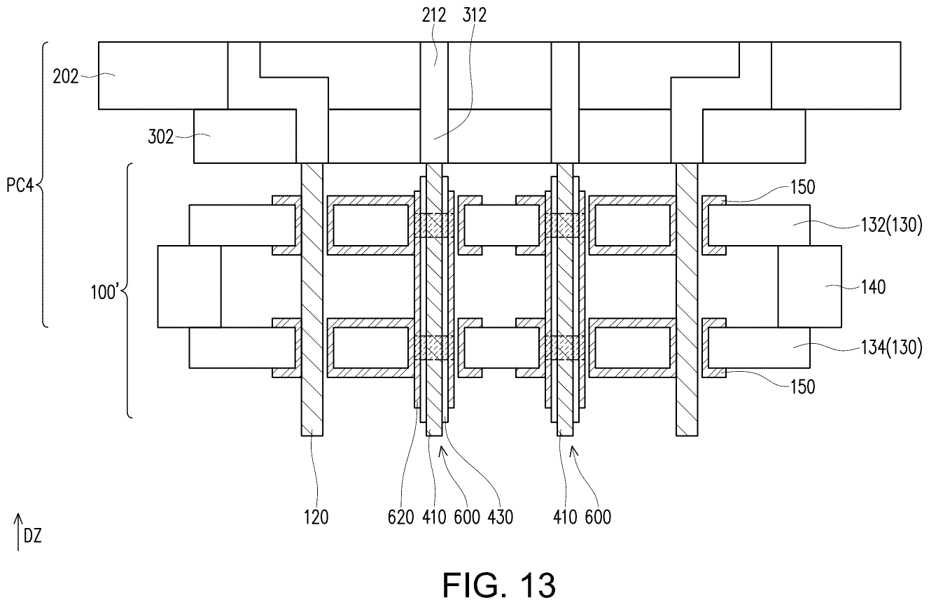

FIG. 13 schematically illustrates a cross-sectional view of a probe card structure in accordance with some embodiments of the disclosure. A probe card structure PC4 shown in FIG. 13 is an implement example obtained by replacing the first probe needle 110 of the probe card structure PC2 in FIG. 2 with the probe needle 600 depicted in FIG. 5. The same reference numbers described in the embodiments of FIG. 2 and FIG. 13 represent the same or equivalent components and thus the descriptions for these components are applicable to both embodiments of FIG. 2 and FIG. 13. Specifically, the probe card structure PC4 includes a needle head 100′, a support plate 202 and an MLO substrate structure 302. The needle head 100′ may be referred to the needle head 100′ depicted in FIG. 12, the support plate 202 may be referred to the support plate 202 depicted in FIG. 2 and the MLO substrate structure 302 may be referred to the MLO substrate structure 302 depicted in FIG. 2. The needle head 100′ may include the probe needles 600, the second probe needles 120, a pair of guide plates 130 including the upper guide plate 132 and the lower guide plate 134, a spacer 140 between the upper guide plate 132 and the lower guide plate 134, the adhesive layers 150 disposed on the surfaces of the upper guide plate 132 and the lower guide plate 134.

Similar to the embodiment of FIG. 2, the support plate 202 at least includes an electrical circuit 212 and the MLO substrate structure 302 at least includes an electric circuit 312. The electric circuit 212 in the support plate 202 is connected to the electric circuit 312 in the MLO substrate structure 302 and the needle core 410 of each probe needle 410 in the probe head 100′ is connected to the corresponding electric circuit 312 in the MLO subtract structure 302. Accordingly, the signals of different probe needles 600 are transmitted by different electric circuits 312 in the MLO subtract structure 302, which forms direct testing channels for different probe needles 600 and is applicable to a high frequency RFIC test. In some embodiments, the high frequency may refer to a frequency greater than 10 GHz. In addition, the signal reflection of each probe needle 600 is reduced since the transmission impedance of the probe needles 600 would be controlled by the electrically grounded needle coat 620. The signal transmission of the probe needles 600 may have high levels of signal integrity and quality.

In light of the above, the probe card structure in some embodiments is implemented by a MEMS (Microelectromechanical System) structure and is configured to achieve an electrical test for a device. The probe head of the probe card structure includes a probe needle, such as an I/O probe needle, having a coaxial structure of a needle core, an isolation layer and a needle coat. In addition, the probe head further includes at least one ground probe needle and adhesive layers disposed on surfaces of the guide plates that guide the positions of the I/O and ground probe needles. The adhesive layer is electrically conductive and the ground probe needle and the needle coat of the I/O probe needle are configured to be in contact with the adhesive layer. During test, the needle core of each I/O probe needle is configured to contact the I/O conductor of the device under test and the needle coat of each I/O probe needle is configured to be electrically grounded. Therefore, the needle coat provides the shielding effect so that the I/O probe needles enable high levels of signal integrity and quality and the cross-talk interference between the I/O probe needles would be mitigated or avoided. The electrically grounded needle coat helps to conduct a high frequency test since signal integrity and quality are improved. In addition, the I/O probe needles are not restricted to a specific relationship with respect to the ground probe needle. The arrangement of the I/O probe needle is thus more flexible.

In some embodiments of the disclosure, a probe needle for testing a device under test (DUT) includes a needle core; a needle coat; and an isolation layer disposed between the needle coat and the needle core, wherein in an extending direction of the needle core, the isolation layer extends exceeding the needle coat and the needle core extends exceeding the isolation layer. The needle core and the needle coat may be electrically independent from each other. In the extending direction of the needle core, the needle coat is spaced from a needle head of the needle core by a first distance and spaced from a needle tip of the needle core by a second distance. In some embodiments, the first distance is ranged from 10 micrometers to 300 micrometers. In some embodiments, the second distance is ranged from 50 micrometers to 600 micrometers. In some embodiments, the first distance is smaller than the second distance. In some embodiments, in the extending direction of the needle core, an extending length of the needle coat is substantially 55% to 90% of an extending length of the needle core. In some embodiments, the needle coat comprises elongation portions extending in the extending direction of the needle core and arranged along a perimeter of the isolation layer, and the elongation portions are spaced from one another. In some embodiments, the needle coat further comprises lateral portions, each of the lateral portions extends continuously between adjacent two of the elongation portions.

In some embodiments of the disclosure, a probe card structure includes a support plate; and a probe head assembled to the support plate. The probe head includes a first probe needle and a second probe needle, wherein the first probe needle includes a needle core; a needle coat, electrically connected to the second probe needle; and an isolation layer covering a first area of a sidewall of the needle core, wherein the needle coat covers a second area of a sidewall of the isolation layer and the first area is larger than the second area. In some embodiments, the probe head further comprises a pair of guide plates, the guide plates are spaced from each other by a gap and the first probe needle and the second probe needle are guided by the pair of the guide plates. In some embodiments, the probe head further includes an adhesive layer disposed on the guide plates and extending between the first probe needle and the second probe needle. In some embodiments, each of the guide plates includes a first guide hole and a second guide hole, the first probe needle extends through the first guide hole, the second probe needle extends through the second guide hole, and the adhesive layer extends surrounding the first guide hole and the second guide hole. In some embodiments, a material of the adhesive layer comprises Cr, Ti, Al, Ni, W, Pt, Au, or a combination thereof. In some embodiments, the isolation layer forms a ring pattern surrounding the needle core in a top view. In some embodiments, the needle coat forms separate patterns around the isolation layer in a top view. In some embodiments, in the extending direction of the needle core, an extending length of the needle coat is substantially 55% to 90% of an extending length of the needle core. In some embodiments, the support plate is a printed circuit board. In some embodiments, the second probe needle is electrically grounded.

In some embodiments of the disclosure, a method of testing a device under test (DUT)., includes providing a probe card structure; and placing the probe card structure on the DUT. The probe card structure includes a support plate and a probe head assembled to the support plate. The probe head includes a first probe needle and a second probe needle, wherein the first probe needle includes a needle core; a needle coat, electrically connected to the second probe needle; and an isolation layer disposed between the needle coat and the needle core, wherein in an extending direction of the needle core, the isolation layer extends exceeding the needle coat and the needle core extend exceeding the isolation layer. In some embodiments, the first probe needle is in contact with an I/O conductor of the DUT and the second probe needle is in contact with a ground conductor of the DUT.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A probe needle for testing a device, comprising:
a needle core;
a needle coat; and
an isolation layer disposed between the needle coat and the needle core, wherein in an extending direction of the needle core, the isolation layer extends exceeding the needle coat and the needle core extends exceeding the isolation layer.

2. The probe needle of claim 1, wherein the needle core and the needle coat are electrically independent from each other.

3. The probe needle of claim 1, wherein in the extending direction of the needle core, the needle coat is spaced from a needle head of the needle core by a first distance and spaced from a needle tip of the needle core by a second distance.

4. The probe needle of claim 3, wherein the first distance is ranged from 10 micrometers to 300 micrometers.

5. The probe needle of claim 3, wherein the second distance is ranged from 50 micrometers to 600 micrometers.

6. The probe needle of claim 3, wherein the first distance is smaller than the second distance.

7. The probe needle of claim 1, wherein in the extending direction of the needle core, an extending length of the needle coat is substantially 55% to 90% of an extending length of the needle core.

8. The probe needle of claim 1, wherein the needle coat comprises elongation portions extending in the extending direction of the needle core and arranged along a perimeter of the isolation layer, and the elongation portions are spaced from one another.

9. The probe needle of claim 8, wherein the needle coat further comprises lateral portions, each of the lateral portions extends continuous between adjacent two of the elongation portions.

10. A probe card structure comprising:
a support plate; and
a probe head assembled to the support plate and comprising a first probe needle and a second probe needle, wherein the first probe needle comprises:
a needle core;
a needle coat, electrically connected to the second probe needle; and
an isolation layer covering a first area of a sidewall of the needle core, wherein the needle coat covers a second area of a sidewall of the isolation layer and the first area is larger than the second area.

11. The probe card structure of claim 10, wherein the probe head further comprises a pair of guide plates, the guide plates are spaced from each other by a gap and the first probe needle and the second probe needle are guided by the pair of the guide plates.

12. The probe card structure of claim 11, wherein the probe head further comprises an adhesive layer disposed on the guide plates and extending between the first probe needle and the second probe needle.

13. The probe card structure of claim 12, wherein each of the guide plates comprises a first guide hole and a second guide hole, the first probe needle extends through the first guide hole, the second probe needle extends through the second guide hole, and the adhesive layer extends surrounding the first guide hole and the second guide hole.

14. The probe card structure of claim 12, wherein a material of the adhesive layer comprises Cr, Ti, Al, Ni, W, Pt, Au, or a combination thereof.

15. The probe card structure of claim 10, wherein the isolation layer forms a ring pattern surrounding the needle core in a top view.

16. The probe card structure of claim 10, wherein the needle coat forms separate patterns around the isolation layer in a top view.

17. The probe card structure of claim 10, wherein in the extending direction of the needle core, an extending length of the needle coat is substantially 55% to 90% of an extending length of the needle core.

18. The probe card structure of claim 10, wherein the second probe needle is electrically grounded.

19. A method of testing a device, comprising:
providing a probe card structure comprising:
a support plate; and
a probe head assembled to the support plate and comprising a first probe needle and a second probe needle, wherein the first probe needle comprises:
a needle core;
a needle coat, electrically connected to the second probe needle; and
an isolation layer disposed between the needle coat and the needle core, wherein in an extending direction of the needle core, the isolation layer extends exceeding the needle coat and the needle core extend exceeding the isolation layer; and
placing the probe card structure on the device.

20. The method of claim 19, wherein the first probe needle is in contact with an I/O conductor of the device and the second probe needle is in contact with a ground conductor of the device.
